(19) United States
(12) Patent Application Publication
(10) Pub. No.: US 2024/0364333 A1
(43) Pub. Date: Oct. 31, 2024

(54) CROSS-COUPLED POWER MULTIPLEXING IN HIGH VOLTAGE APPLICATIONS

(71) Applicant: Intel Corporation, Santa Clara, CA (US)

(72) Inventor: Raymond Chong, Bayan Lepas (MY)

(73) Assignee: Intel Corporation, Santa Clara, CA (US)

(21) Appl. No.: 18/140,481

(22) Filed: Apr. 27, 2023

(51) Int. Cl. H03K 17/693

(52) U.S. Cl. CPC H03K 17/693; H03K 19/017509

(57) ABSTRACT

Multiplexing circuitry comprises first switch and second switches coupled in series between a first node to receive a first supply voltage and a second node to provide an output voltage, and third and fourth switches coupled in series between a third node to receive a second supply voltage and the second node. First circuitry is to generate a first switch control signal to operate the first switch. Second circuitry is to generate a second switch control signal to operate the third switch. A first driver circuit is to generate a third switch control signal to operate the second switch. A second driver circuit is to generate a fourth switch control signal to operate the fourth switch. In a cross-coupled arrangement, the third switch control signal is based on the second switch control signal, and the fourth switch control is based on the second switch control signal.

### BACKGROUND

### 1. Technical Field

This disclosure generally relates to power sources for circuitry and more particularly, but not exclusively, to multiplexing circuitry for switching between different power sources.

### 2. Background Art

Power multiplexing may be used in a system to transition between different primary sources, or to transition to a secondary power source when the main power supply fails. Power multiplexing also allows a system to share the same piece of hardware, such as compensation circuitry, with dual supply sources, thereby reducing physical area cost.

In systems supplied by two power sources, protocols are defined for the sources, such as procedures for turning the sources on and off, and voltage levels. If the rules are not followed, the circuitry being supplied with power may be damaged.

### BRIEF DESCRIPTION OF THE DRAWINGS

The various embodiments of the present invention are illustrated by way of example, and not by way of limitation, in the figures of the accompanying drawings and in which:

FIG. 1 shows a high-level, functional block diagram illustrating features of a device comprising level shifting and power multiplexing circuitry according to an embodiment;

FIG. 2 shows functional block diagram illustrating features of a device comprising level shifting and power multiplexing circuitry according to various embodiments;

FIG. 3 is a schematic diagram illustrating the driver circuitry employed in the power multiplexing circuitry of FIG. 2, according to various embodiments;

FIG. 4 shows a timing diagram illustrating a power supply ramp up operation according to an embodiment;

FIG. 5 shows a flow diagram illustrating a method for operating a power multiplexer according to an embodiment; and

FIG. 6 illustrates a computer system or computing device comprising voltage level shifting and power multiplexing circuitry, in accordance with some embodiments.

### DETAILED DESCRIPTION

Embodiments described herein variously provide techniques and/or mechanisms to efficiently regulate a delivery of power. In some embodiments, power multiplexer circuitry enables an electronic system to be selectively provided power with any of multiple power sources. For example, power multiplexer circuitry is operated to selectively enable two primary power sources each to supply power, at different times, to some or all of a given electronic system. In one such embodiment, power multiplexer circuitry is operated to regulate power delivery with a primary power and a backup power source. In some embodiments, the power multiplexer circuitry includes (or operates in combination with) compensation circuitry. For example, such compensation circuitry can adjust the voltage or current level which is provided with a given power supply—e.g., to meet requirements of the circuitry being supplied power. A system may be provided with power multiplexing circuitry, which permits it to use either of two different power sources and allows both power sources to share a single compensation circuit, if required. The sharing of a compensation circuit reduces the physical area of an integrated circuit (IC).

In systems supplied by two power sources, protocols are typically defined for the power sources. For example, such protocols may specify operations for turning the power sources on and off. Such protocols may also specify voltage levels to be provided with the power sources. In various field-programmable gate array (FPGA) applications, for example, the sequence of operations to turn a power supply on or off are not always guaranteed. If the operations in a protocol are not followed according to said sequence, the timing of when power is supplied or withdrawn is unpredictable. If power is supplied or withdrawn in a way that is not predicted, the circuitry being supplied with power can be damaged. In a system being supplied with power through power multiplexing circuitry, if a power source is powered down without following protocol, the circuitry being supplied with power may receive a current spike. The current spike can damage the circuitry.

In a system being suppled power with conventional power multiplexing circuitry, if a power supply ramps up or down in an unpredictable manner, the circuitry being supplied with power can be damaged. To mitigate the risk of damage to circuitry being supplied with power, a system with conventional power multiplexing circuitry typically includes a power detector and power management unit. The power detector performs monitoring to detect the availability of power being supplied by each power supply. The power detector then indicates this availability to the power management unit, which controls the power multiplexing circuitry to protect load circuitry which is being supplied with power. While the power management unit and power detector facilitate the protection of load circuitry, these units add to the cost of and physical area required on an IC. An advantage of the power multiplexing circuitry according to the embodiments described herein is the provisioning of relatively space efficient and/or cost efficient circuitry to control power multiplexing functionality.

Some circuitry operates in a “high” voltage power domain, e.g., a gate-source voltage or gate-drain voltage above 1.1V and up to 1.8V. Power multiplexer circuitry supplying power to a high voltage power domain may use transistors with a relatively thick gate oxide layer to prevent electrical overstress to the transistors. However, use of transistors with a thick gate oxide layer result in a significant voltage drops across power switches during a high current load. A large voltage drop can be undesirable because the circuitry being supplied power by the power multiplexer will receive a supply voltage that is lower than the target voltage. Low-power double data rate memory, e.g., LPDDR5 and LPDDR4×, and double data rate memory, e.g., DDR5, and DDR4, typically require supply voltages between 1.05V and 1.2V. Accordingly, power multiplexer circuitry employing thick gate oxide transistors are generally not suitable for use with these memories.

In some systems, it is desirable to use transistors with a relatively thin gate oxide layer. Use of transistors with a thin gate oxide layer results in lower voltage drops across power switches under a high current load in comparison to transistors with a thick gate oxide layer. For example, it can be desirable to use transistors with a thin gate oxide layer in power multiplexing circuitry supplying power to low-power double data rate memory or double data rate memory. In an embodiment, a relatively thin gate oxide layer corresponds with a gate-source voltage or gate-drain voltage of a transistor less than 1.1V. However, when thin gate oxide transistors are used in a high voltage power domain, the transistors can be electrically overstressed. An advantage of embodiments described herein is that transistors with a thin gate oxide layer may be used in power multiplexing circuitry operating in a high voltage power domain without electrically overstressing transistors in the power multiplexing circuitry.

In some embodiments, a power multiplexer comprises at least two switched circuit paths which are variously operable to facilitate multiplexing functionality. In this particular context, “switched circuit path” refers to a path, in circuitry, which comprises one or more switch elements—e.g., including one or more transistors. The one or more switch elements of a given switched circuit path are operable to selectively enable (or disable) a conduction of current from one end of the path to another end of the path. In an embodiment, the at least two switched circuit paths of a power multiplexer facilitate the selective multiplexing between any of two or more power supplies which are to be coupled to the power multiplexer.

In some embodiments, such a power multiplexer further comprises cross-coupled driver circuits—e.g., driver circuits which are arranged in a cross-coupled configuration (relative to each other) with two switched circuit paths of the power multiplexer. As described herein, such a cross-coupled configuration enables some embodiments to provide a space efficient solution for improved multiplexing between power sources.

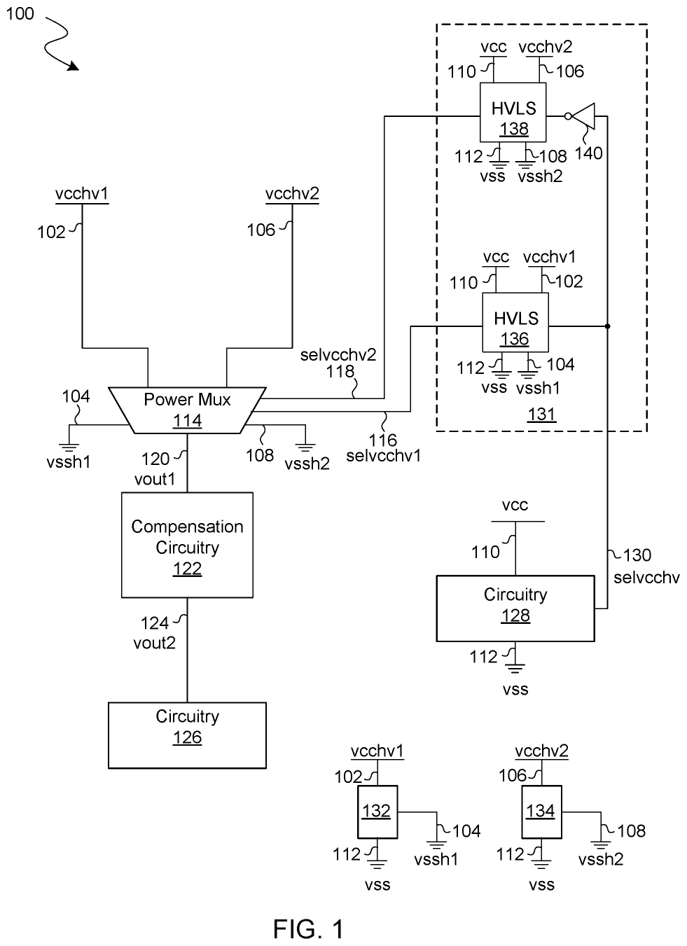

FIG. 1 shows a high-level, functional block diagram illustrating features of a device 100 (e.g., an integrated circuit) comprising a high-voltage level shifting unit 131 and power multiplexing circuitry 114 according to an embodiment. The device 100 includes a first power domain, a second power domain, and a third power domain. The first power domain comprises voltages ranging from a first (relatively high, or “upper”) supply voltage vcchv1 102 to a first (relatively low, or “lower”) supply voltage vssh1 104. The second power domain comprises voltages ranging from a second (upper) supply voltage vcchv2 106 to a second (lower) supply voltage vssh2 108. The third power domain comprises voltages ranging from a third (upper) supply voltage vcc 110 to a third (lower) supply voltage vss 112. The power multiplexing circuitry 114 supplies power from the first power domain when a select signal selvcchv1 116 is asserted. The power multiplexing circuitry 114 supplies power from the second power domain when a select signal selvcchv2 118 is asserted. The power multiplexing circuitry 114 supplies power, with an output voltage vout1 120 to compensation circuitry 122. Compensation circuitry 122 supplies power, via an output vout2 124, to first circuitry 126. In some embodiments, compensation circuitry 122 may be omitted and power multiplexing circuitry 114 supplies power directly to first circuitry 126. An advantage of embodiments that include compensation circuitry 122 is that two different power sources can share a single compensation circuit. The sharing of a single compensation circuit reduces the physical area of the IC.

In embodiments, the supply voltage vssh1 104 is generated from the supply voltage vcchv1 102. In embodiments, the supply voltage vssh2 108 is generated from the supply voltage vcchv2 106. Generating lower supply voltages 104 and 108 from upper supply voltages vcchv1 102 and vcchv2 106 (respectively) may be advantageous. Generating a lower supply voltage from an upper supply voltage causes the upper and lower supply voltage rails to ramp up and down together. The transistors in level shifters 136 and 138 may have thin gate oxide layers. It may help to avoid electrical overstress on transistors in level shifters 136 and 138 if the lower supply voltage and the associated upper supply voltage ramp up and down together. In embodiments, the device 100 includes circuitry 132 to generate supply voltage vssh1 104 from supply voltage vcchv1 102. In embodiments, the device 100 includes circuitry 134 to generate supply voltage vssh2 108 from supply voltage vcchv2 106. In embodiments, circuitry 132 and circuitry 134 each comprise a resistive element.

An enable (or select) signal selvcchv 130 is provided by second circuitry 128. The second circuitry 128 may be configured to perform any desired function, e.g., logic and/or memory functions. In embodiments, second circuitry 128 includes logic for selecting one power source from two or more power sources according to a criterion and/or a condition. Second circuitry 128 includes logic to generate enable signal, selvcchv 130. The first circuitry 126 may be configured to perform any desired function, e.g., logic and/or memory functions. In embodiments, first circuitry 126 may comprise a field-programmable gate array (FPGA), low-power double data rate memory, double-data rate memory, and/or low-voltage differential signaling (LVDS) input/output (I/O) circuitry. The first circuitry 126 operates using power supplied by voltage sources in either the first or second power domain. The second circuitry 128 operates using power supplied by voltage sources in the third power domain.

In embodiments, the upper supply voltage vcchv1 102 level in the first power domain is equal to the upper supply voltage vcchv2 106 level in the second power domain. For example, supply voltage vcchv1 102 and supply voltage vcchv2 106 may both equal 1.5 V. In other embodiments, the upper supply voltage levels in the first and second power domain may be different. For example, supply voltage vcchv1 102 may equal 1.5 V and supply voltage vcchv2 106 may equal 1.3 V. In embodiments, the upper supply voltage level in the first power domain is higher than the upper supply voltage in the third power domain. For example, supply voltage vcchv1 102 equals 1.5 V and supply voltage vcchv2 106 equals 1.0 V. In embodiments, the upper supply voltage level in the second power domain is higher than the upper supply voltage in the third power domain. For example, supply voltage vcchv2 106 equals 1.3 V and supply voltage vcchv2 106 equals 1.0 V. In embodiments, the lower supply voltage level in the first power domain is higher than the lower supply voltage level in the third power domain. Similarly, in embodiments, the lower supply voltage level in the second power domain is higher than the lower supply voltage level in the third power domain. For example, supply voltage vssh1 104 and supply voltage vssh2 108 may both equal 0.5 V, and supply voltage vss 112 may equal 0.0 V. Because the lower supply voltage levels in the first and second power domain can be higher than the lower supply voltage levels in the third power domain, the supply voltage vssh1 104 and supply voltage vssh2 108 may be referred to herein as “elevated ground rails.”

The device 100 comprises high-voltage level shifting (HVLS) unit 131. In embodiments, HVLS unit 131 performs two functions. First, the voltage level of an input signal is shifted up or down. Second, the voltage range of the input signal is modified. The HVLS unit 131 comprises a first level shifter 136 and a second level shifter 138. Second circuitry 128 provides the select signal selvcchv 130 as inputs to the first level shifter 136 and to an inverter 140. An inverted or complementary version of select signal selvcchv 130 is output by the inverter 140 and provided as an input to the second level shifter 138. The select signal selvcchv 130 and the inverted version of select signal selvcchv 130 are represented by voltages in the third power domain. A logic one of the select signal selvcchv 130 may correspond with supply voltage vcc 110. A logic zero of the select signal selvcchv 130 may correspond with supply voltage vss 112. In embodiments, the HVLS unit 131 shifts up the voltage level of select signal selvcchv 130 and its complementary signal. In embodiments, the HVLS unit 131 modifies the voltage level of select signal selvcchv 130 and its complementary signal.

As shown in FIG. 1, each of the level shifters 136 and 138 is coupled with two power domains. The first level shifter 136 is coupled with supply voltages of the first and third power domains. Specifically, first level shifter 136 is coupled with vcchv1 and vssh1 of the first power domain, and vcc and vss of the third power domain. The second level shifter 138 is coupled with supply voltages of the second and third power domains. Specifically, second level shifter 138 is coupled with vcchv2 and vssh2 of the second power domain, and vcc and vss of the third power domain. The output of the first level shifter 136 is provided to power multiplexing circuitry 114 as signal selvcchv1. The signal selvcchv1 comprises voltages available in the first power domain. The output of the second level shifter 138 is provided to power multiplexing circuitry 114 as signal selvcchv2. The signal selvcchv2 comprises voltages available in the second power domain. Accordingly, the first level shifter 136 receives a signal having a voltage level available in the third power domain and outputs a signal having a voltages level available in the first power domain. For example, a logic high of selvcchv1 may be approximately equal to supply voltage vcchv1, and a logic low of selvcchv1 may be approximately equal to supply voltage vssh1 104. Similarly, the second level shifter 138 receives a signal having a voltage level available in the third power domain and outputs a signal having a voltage level available in the second power domain. For example, a logic high of selvcchv2 may be approximately equal to the supply voltage vcchv2, and a logic low of selvcchv2 may be approximately equal to supply voltage vssh2.

Each of the first and second level shifters 136 and 138 modify the voltage range of the input signal. The term “full-swing,” as used herein, refers to the possible voltage range of the signal input to one of the first and second level shifters 136 and 138. The terms “partial-swing” and “half-swing,” as used herein, refers to the signal output from one of the first and second level shifters 136 and 138. In embodiments, the first level shifter 136 transforms a “full” swing signal (vcc-vss) to a “partial” swing signal (vcchv1-vssh1). In embodiments, the second level shifter 138 transforms a “full” swing signal (vcc-vss) to a “partial” swing signal (vcchv2-vssh2). In one example, the range of voltages received by the first level shifter 136 is (vcc-vss=) 1.1 V and the range of voltages output is (vcchv1−vssh1=) 0.8 V. In another example, the range of voltages received by the second level shifter 138 is (vcc−vss=) 1.1 V and the range of voltages output is (vcchv2−vssh2=) 0.7 V. In embodiments, the first and second level shifters 136 and 138 each transform a signal in a first range of voltages, e.g. 0.0-1.1 V, to a signal in a second range of voltages, e.g. 0.6-1.4 V. In some embodiments, the second range of voltages is less than the first range of voltages. In some embodiments, the lower supply voltage in the second range of voltage is an elevated ground rail with respect to the lower supply voltage in the first range of voltages.

In some embodiments, a full-swing voltage range comprises voltages available in the third power domain. Specifically, a full-swing voltage range comprises voltages ranging from upper supply voltage vss to lower supply voltage vss. In an embodiment vss is a ground rail. In some embodiments, a partial- or half-swing voltage range comprises voltages available in the first power domain or second power domain. In some embodiments, a partial- or half-swing voltage range comprises voltages ranging from upper supply voltage to lower supply voltage. In embodiments vssh1 and vssh2 are elevated ground rails. The first level shifter 136 and second level shifter each modify the voltage range of an input signal from a full-swing signal to a partial-swing signal. In some embodiments, the partial-swing range of voltages may be less than the full-swing voltage range, however, this is not required. In some embodiments, the partial-swing range of voltages may be equal to or greater than the full-swing range of voltages. Accordingly, references herein to a partial- or half-swing driver, should not be interpreted to mean that the output of the driver is necessarily less than or half of a full-swing input to a level shifter.

In some embodiments, both the full-swing voltage range and the partial-swing voltage range are in a range than does not cause electrical overstress to some or all switching transistors. In one such embodiment, both the full-swing voltage range and the partial-swing voltage range are less than 1.1V (for example).

The power multiplexing circuitry 114 receives supply voltages from the first and second power domains. In particular, power multiplexing circuitry 114 receives supply voltage vechv1 102 and supply voltage vssh1 104. The power multiplexing circuitry 114 also receives supply voltage vcchv2 106 and supply voltage vssh2 108. The power multiplexing circuitry 114 supplies power from one of the two power domains via output voltage vout1 120.

In one example embodiment, a first power supply (e.g., illustrated by circuitry 132), which provides the supply voltage vcchv1, is coupled to power multiplexing circuitry 114 via a first input terminal of power multiplexing circuitry 114. Furthermore, a second power supply (e.g., illustrated by circuitry 134), which provides the supply voltage vcchv2, is coupled to power multiplexing circuitry 114 via a second input terminal of power multiplexing circuitry 114. In an embodiment, power multiplexing circuitry 114 comprises a first switched circuit path between the first input terminal and the output terminal. Furthermore, power multiplexing circuitry 114 further comprises a second switched circuit path between the second input terminal and the output terminal. In one such embodiment, driver circuits (not shown) of power multiplexing circuitry 114 are coupled to variously operate respective switch elements of these switched circuit path.

For example, a first driver circuit and a second driver circuit of power multiplexing circuitry 114 are arranged in a cross-coupled configuration with the first switched circuit path and the second switched circuit path. In this particular context, “cross-coupled” refers herein to the characteristic of a first correspondence—between two driver circuits and two switched circuit paths—being the opposite of a second correspondence between the two driver circuits and the two switched circuit paths. In one example embodiment, the first correspondence is with respect to how respective input terminals of the two driver circuits are each coupled to a different respective one of the switched circuit paths. By contrast, the second correspondence is with respect to how respective output terminals of the two driver circuits are each coupled to a different respective one of the switched circuit paths.

In an illustrative scenario according to one embodiment, the first driver circuit of power multiplexing circuitry 114 is coupled to the first switched circuit path of power multiplexing circuitry 114 via an output of that first driver circuit. The first driver circuit is further coupled to the second switched circuit path of power multiplexing circuitry 114 via an input of the first driver circuit. By contrast, the second driver circuit of power multiplexing circuitry 114 is coupled to the second switched circuit path via an output of the second driver circuit. Furthermore, the second driver circuit of power multiplexing circuitry 114 is coupled to the first switched circuit path via an input of the second driver circuit.

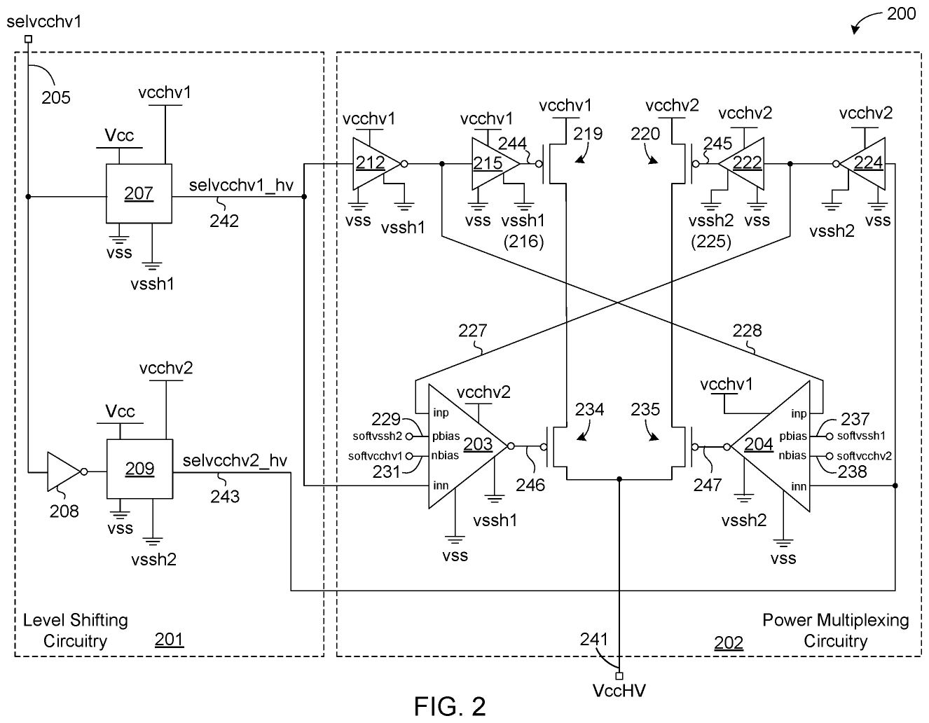

In embodiments, two or more switched circuit paths the power multiplexing circuitry 114 each comprise a respective set of two or more stacked transistors. For example, one such switched circuit path comprises two transistors connected in series between either the supply voltage vcchv1 102, or the supply voltage vcchv2, and output voltage vout1. In one such embodiment, one transistor of said switched circuit path is controlled by one of the driver circuits in a cross-couple control technique described below. The stacked transistors of such a switched circuit path are variously configured each for operation as a respective switch. The cross-coupled circuit architecture of various embodiments enables a switch to shut off when either one of the supply voltages vcchv1 102, vcchv2 106 is higher than the other. Additionally or alternatively, such a cross-coupled circuit architecture enables the switch to shut off when one of the supply voltages vcchv1 102, vcchv2 106 ramps up or down at a rate that is different from the other one of supply voltages vcchv1 102, vcchv2 106. An example of power multiplexing circuitry 114 is further described with reference to FIG. 2.

FIG. 2 shows features of a device 200 (e.g., an integrated circuit) comprising level shifting circuitry 201 and power multiplexing circuitry 202 according to various embodiments. The level shifting circuitry 201 comprises level shifters 207 and 209, and inverter 208. The power multiplexing circuitry 202 comprises two sets of power switches, and driver circuitries 203 and 204. A first switched circuit path, which comprises transistor 219 and transistor 234, extends between a first input terminal of power multiplexing circuitry 202, and an output terminal of power multiplexing circuitry 202. Transistors 219 and 234 are connected in series between the first input terminal and the output terminal. The first input terminal is to be coupled to receive a supply voltage vcchv1, and the output terminal is to provide an output voltage VccHV 241. A second switched circuit path, which comprises transistor 220 and transistor 235, extends between a second input terminal of power multiplexing circuitry 202, and the output terminal. Transistors 220 and 235 are connected in series between the second input terminal and the output terminal. The second input terminal is to be coupled to receive a supply voltage vcchv2. The power multiplexing circuitry 202 also includes intermediate inverters 212 and 224, and buffers 215 and 222.

In the example embodiment shown, driver circuitry 203 and driver circuitry 204 are arranged in a cross-coupled configuration (relative to each other) with the first switched circuit path and the second switched circuit path of power multiplexing circuitry 202. More particularly, driver circuitry 203 is coupled to the first switched circuit path—which comprises transistors 219, 234—via an output of that driver circuitry 203 (wherein said output is coupled at node 246). The driver circuitry 203 is further coupled to the second switched circuit path—which comprises transistors 220, 235—via an input inp of the driver circuitry 203 (wherein conductive line 227 extends to said input inp). By contrast, driver circuitry 204 is coupled to the second switched circuit path via an output of that driver circuitry 204 (wherein said output is coupled at node 247). Furthermore, driver circuitry 204 is coupled to the first switched circuit path via an input inp of that driver circuitry 204 (wherein conductive line 228 extends to said input inp).

The level shifting circuitry 201 receives enable signal selvcchv1 on conductive line 205. Level shifter 207 is coupled with intermediate inverter 212 via conductive line 242. Level shifter 207 provides a signal selvcchv1_hv via line 242 to intermediate inverter 212. Intermediate inverter 212 is coupled with buffer 215. Buffer 215 is coupled with the gate of transistor 219. Accordingly, an inverted version of signal selvcchv1_hv 242 controls transistor 219. Level shifter 209 is coupled with intermediate inverter 224 via conductive line 243. Level shifter 209 provides a signal selvcchv2_hv 243 to intermediate inverter 224. Intermediate inverter 224 is coupled with buffer 222. Buffer 222 is coupled with the gate of transistor 220. Accordingly, an inverted version of signal selvcchv2_hv 243 controls transistor 220. The enable signal selvcchv1_hv selects (turns on) one of two power switches. Inverter 208 is provided before level shifter 209 because the selection of one of the power sources is always in a mutual exclusive condition. Only one set of the power switches should be turned on at a time.

Driver circuitry 203 and 204 each include a respective input inp and another respective input inn. Driver circuitry 203 is coupled with level shifter 207 via conductive line 242. Driver circuitry 203 receives selvcchv1_hv 242 from level shifter 207 on its input inn. Driver circuitry 203 is also coupled with the output of intermediate inverter 224 via conductive line 227. Driver circuitry 203 receives, via its input inp, the inverted version of signal selvcchv2_hv 243, where said inverted signal functions as a signal (a “selection signal” herein) which is indicative of a selected multiplexing mode. Coupling the output of intermediate inverter 224 with driver circuitry 203 is an example of a cross-couple control technique. Driver circuitry 204 is coupled with level shifter 209 via conductive line 243. Driver circuitry 204 receives at its input inn selvcchv2_hv 243 from level shifter 209. Driver circuitry 204 is also coupled with the output of intermediate inverter 212 via conductive line 228. Driver circuitry 204 receives, via its input inp, the inverted version of signal selvcchv1_hv 242, where said inverted signal functions as another selection signal which is indicative of the selected multiplexing mode. Coupling the output of intermediate inverter 212 with driver circuitry 204 is another example of the cross-couple control technique.

Driver circuitry 203 and 204 each include a pbias input and a nbias input. Driver circuitry 203 is coupled to receive signal softvssh2 at its pbias input via conductive line 229. In addition, driver circuitry 203 is coupled to receive signal softvcchv1 at its nbias input via conductive line 231. Driver circuitry 204 is coupled to receive signal softvssh1 at its pbias input via conductive line 237. In addition, driver circuitry 204 is coupled to receive signal softvcchv2 at its nbias input via conductive line 238.

The level shifting circuitry 201 shifts the voltage level of the received signal up or down. Each of the level shifters 207 and 209 is coupled with two power domains. The first level shifter 207 is coupled with upper and lower supply voltages of first and third power domains. Specifically, first level shifter 207 is coupled with vcchv1 and vssh1 of the first power domain. The first level shifter 207 is also coupled with voltages vcc and vss of the third power domain. The second level shifter 209 is coupled with supply voltages of second and third power domains. Specifically, second level shifter 209 is coupled with vcchv2 and vssh2 of the second power domain. The second level shifter 209 is also coupled with voltages vcc and vss of the third power domain. Level shifter 207 converts a logic high enable signal selvcchv1 having a voltage level of vcc to a signal selvcchv1_hv 242 having a voltage level of vcchv1. A logic low enable signal is converted from a signal having a voltage level of vss to signal selvcchv1 having a voltage level of vssh1. Similarly, level shifter 209 converts the complement of a logic high enable signal selvcchv1, i.e., a logic low, from a voltage level of vss to a signal selvcchv2_hv having a voltage level of vssh2. The complement of a logic low enable signal selvcchv1, i.e., a logic high, is converted from a signal having a voltage level of vcc to a signal selvcchv2_hv 243 having a voltage level of vcchv2. The level shifting circuitry 201 convert an enable signal selvcchv1 from core supply voltage vcc to signals corresponding with “high” voltage supplies vcchv1 and vcchv2. The first, second, and third power domains may be the same as or similar to the like-named power domains described with respect to FIG. 1.

The level shifting circuitry 201 also modifies the voltage swing of the received signal. In embodiments, the level shifter 207 transforms the full swing signal (vcc-vss) to a partial swing signal selvcchv1_hv 242. Level shifter 209 transforms the full swing signal (vcc-vss) to a partial swing signal selvcchv2_hv 243. The voltage selvcchv1_hv 242 ranges from vcchv1 to vssh1. The voltage selvcchv2_hv 243 ranges from vcchv2 to vssh2. As noted above, vssh1 and vssh2 may be referred to as “elevated” ground rails with respect to vss 250a and 250b. In an embodiment, level shifting circuitry 201 may be the same as or similar to the HVLS unit 131 described with respect to FIG. 1.

Intermediate inverter 212 is coupled with supply voltage vcchv1 and supply voltage vssh1 213 of the first power domain. Intermediate inverter 212 is also coupled with vss. Intermediate inverter 224 is coupled with supply voltage vcchv2 and supply voltage vssh2 225 of the second power domain. Intermediate inverter 224 is also coupled with vss.

Buffer 215 is coupled with supply voltage vcchv1 and supply voltage vssh1 216 of the first power domain. Buffer 215 is also coupled with vss. Buffer 222 is coupled with supply voltage vcchv2 and supply voltage vssh2 225 of the second power domain. Buffer 222 is also coupled with vss.

Driver circuitry 203 is coupled with supply voltage vcchv2 and supply voltage vssh1 233. Driver circuitry 203 is also coupled with vss. Because of this coupling, driver circuitry 203 generates a signal having an output voltage ranging from a lower supply voltage in the first power domain to an upper supply voltage in the second power domain. Driver circuitry 204 is coupled with supply voltage vcchv1 and supply voltage vssh2. Because of this coupling, driver circuitry 204 generates a signal having an output voltage ranging from a lower supply voltage in the second power domain to an upper supply voltage in the first power domain.

In various embodiments, devices 100 and 200 are subject to the following three conditions:

First, in some embodiments, a difference between the supply voltage vcchv1 and the supply voltage vssh1 should be less than 1.069 V, i.e., vcchv1−vssh1<1.069 V. Similarly, a difference between the supply voltage vcchv2 and the supply voltage vssh2 should be less than 1.069 V, i.e., vcchv2−vssh2<1.069 V. This condition may ensure that the gate junctions of devices are within electrical overstress limits. A maximum voltage swing of 1.069 V may be higher or lower in other embodiments, e.g., with transistors in different technologies, dimensions, or features. In various embodiments, the supply voltage vssh1 may be generated from the supply voltage vcchv1, and the supply voltage vssh2 may be generated from the supply voltage vcchv2. This causes each lower rail to ramp up and down together with its upper rail. Generating a lower supply voltage from an upper supply voltage in a power domain may help to avoid electrical overstress on transistors in level shifters 207 and 209. In embodiments, transistors in level shifters 207 and 209 have thin gate oxide layers. In an embodiment, the device 200 includes circuitry (similar to that shown in FIG. 1) to respectively generate supply voltage vssh1 and supply voltage vssh2.

Second, in some embodiments, a difference between the supply voltage vcchv1, and the supply voltage vssh1 should be greater than 0.7 V, i.e., vcchv1−vssh1>0.7 V. Similarly, a difference between the supply voltage vcchv2 and a supply voltage vssh2 should be greater than 0.7 V, i.e., vcchv2−vssh2>0.7 V. A minimum voltage swing of 0.7 V may ensure that devices, e.g., transistors, are fully turned on and have a high drivability strength. The minimum voltage swing of 0.7 V may be higher or lower in other embodiments, e.g., with transistors in different technologies, dimensions, or features.

Third, the supply voltage vcchv1 must be provided to level shifter 207, intermediate inverter 212, buffer 215, switch 219, and driver circuitry 204. In addition, the supply voltage vcchv2 must be provided to level shifter 209, intermediate inverter 224, buffer 222, switch 220, and driver circuitry 203.

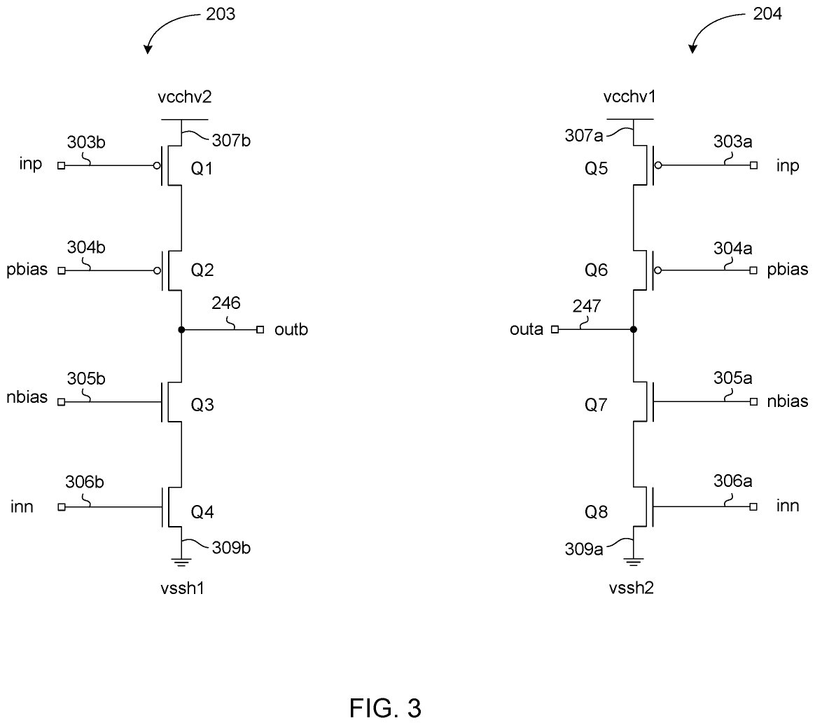

FIG. 3 is a schematic diagram illustrating one example of the driver circuitry 203 and 204 employed in the power multiplexing circuitry 202 of FIG. 2, according to various embodiments. Each driver generates a signal having an output voltage ranging from a lower supply voltage in a first power domain to an upper supply voltage in a second power domain. Each of driver circuitries 203 and 204 may be a two-rail half-swing inverter comprising stacked PMOS and NMOS devices. In a conventional inverter, the output swings from the supply rail to the ground rail within one power domain. In contrast, the dual-rail half-swing drivers 203 and 204 generate an output determined by voltages in two power domains. The output is based on an upper supply rail in one power domain to a lower supply rail in another power domain.

Driver circuitry 203 is coupled with supply voltage vcchv2 and supply voltage vssh1 233. Driver circuitry 203 generates an output that swings between approximately the supply voltage vcchv2 and the supply voltage vssh1 to 233. For driver circuitry 203, the supply voltage vssh1 233 is generated from supply voltage vcchv1. As shown in FIG. 2, driver circuitry 203 is also coupled with the supply voltage vss. Driver circuitry 204 is coupled with supply voltage vcchv1 and supply voltage vssh2. Driver circuitry 204 generates an output that swings between approximately the supply voltage vcchv1 and the supply voltage vssh2. As shown in FIG. 2, driver circuitry 204 is coupled with the supply voltage vss. For driver circuitry 203, supply voltage vssh2 is generated from supply voltage vcchv2.

Driver circuitry 203 comprises two stacked PMOS devices Q1 and Q2 and two stacked NMOS devices Q3 and Q4. Transistors (or power switches) Q1 and Q2 are coupled in series with each other between a first node 307b and a second node 246. Second node 246 may provide a switch control signal outb which is output by driver circuitry 203 based on an input selection signal 303b. Transistor Q1 receives a first supply voltage, e.g., supply voltage vcchv2, at the first node 307b. Transistors (or power switches) Q3 and Q4 are coupled in series with each other between a third node 309b and the second node 246. The transistor Q4 receives a second supply voltage, e.g., supply voltage vssh1 233, at the third node 309b. The gate of each of the devices Q1, Q2, Q3, and Q4 is driven by a different input.

The gate of Q1 is coupled to receive selection signal 303b. The gate of Q1 may be referred to herein as inp. Selection signal 303b is generated in a high-voltage power domain that swings between vcchv2 and vssh2. In an embodiment, intermediate inverter 224 generates the input selection signal 303b.

The gate of Q2 is coupled with p-biasing signal 304b. The gate of Q2 may be referred to herein as pbias. The p-biasing signal 304b is generated from the same upper supply voltage supply as that of the driver circuitry 203, e.g., supply voltage vcchv2. In an embodiment, the p-biasing signal 304b is a “soft” connection to vssh2. The purpose of the pbias signal is to provide EOS protection to the PMOS devices in driver circuitry 203.

The gate of Q3 is coupled with n-biasing signal 305b, referred to herein as nbias. The n-biasing signal 305b may be generated from supply voltage vcchv1 via a “soft” connection. The purpose of the nbias signal is to provide EOS protection to the NMOS devices in driver circuitry 203. The gate of Q4 is coupled with input selection signal 306b.

The gate of Q4 may be referred to herein as inn. Input selection signal 306b is generated in a high voltage power domain that swings between vcchv1 and vssh1. In an embodiment, input selection signal 306a is generated by level shifter 207. In an embodiment, devices Q1, Q2, Q3, and Q4 have thin gate oxide layers. The particular gate oxide thickness varies based on the process technology, but, in various embodiments, the criteria to be a thin gate oxide is that the voltage difference between gate-source-drain is always below 1.069V.

Driver circuitry 204 comprises two stacked PMOS devices Q5 and Q6 and two stacked NMOS devices Q7 and Q8. Transistors (or power switches) Q5 and Q6 are coupled in series with each other between a fourth node 307a and a fifth node 247. The fifth node 247 may provide a switch control signal outa which is output by driver circuitry 204 based on an input selection signal 303a. Transistor Q5 receives a first supply voltage, e.g., supply voltage vcchv1, at the fourth node 307a. Transistors (or power switches) Q7 and Q8 are coupled in series with each other between a sixth node 309a and the fifth node 247. The transistor Q8 receives a second supply voltage, e.g., supply voltage vssh2, at the sixth node 309a. The gate of each of the devices Q5, Q6, Q7, and Q8 is driven by a different input.

The gate of Q5 is coupled to receive the selection signal 303a via input inp. Selection signal 303a is generated in a high-power voltage domain that swings between vcchv1 and vssh1. In an embodiment, intermediate inverter 212 generates input selection signal 303a.

The gate of Q6 is coupled with p-biasing signal 304a, referred to herein as pbias. The p-biasing signal 304a is generated from the same upper supply voltage supply as that of the driver circuitry 204, e.g., supply voltage vcchv1. In an embodiment, p-biasing signal 304a is a “soft” connection to vssh2. The purpose of the pbias signal is to provide EOS protection to the PMOS devices in driver circuitry 204.

The gate of Q7 is coupled with n-biasing signal 305a, referred to herein as nbias. The n-biasing signal 305a may be generated from supply voltage vcchv2 via a “soft” connection. The purpose of the nbias signal is to provide EOS protection to the NMOS devices in driver circuitry 204.

The gate of Q8 is coupled with input selection signal 306a, referred to herein as inn. Input selection signal 306a is generated in a high-power voltage domain that swings between vcchv2 and vssh2. In an embodiment, input selection signal 306a is generated by level shifter 209. In an embodiment, devices Q5, Q6, Q7, and Q8 have thin gate oxide layers. The particular gate oxide thickness varies based on the process technology, but, in various embodiments, the criteria to be a thin gate oxide is that the voltage difference between gate-source-drain is always below 1.069V.

Advantageously, drivers 203 and 204 can ensure that electrical overstress (EOS) scenarios are handled properly. The output of driver circuitry 203 is coupled with the gate of transistor 234 via node 246. The output of driver circuitry 204 is coupled with the gate of transistor 235 via node 247. Transistors 234 and 234 may be referred to herein as power switches. In this regard, another advantage of drivers 203 and 204 is that they guarantee that nodes 246 and 247 are driven with correct potentials. This avoids reverse current flowing through the transistors 234 and 235 from one supply to the other when the supply voltage vcchv1 and supply voltage vcchv2 have a potential voltage difference between them.

Referring again to FIG. 2, supply voltage vcchv1 is coupled with output voltage VccHV 241 when the left-side transistors 219 and 234 are turned on. This occurs when a switch control signal at node 244 (to control transistor 219) is driven to vssh1 216, and another switch control signal at node 246 (to control transistor 234) is driven to vssh1 233. At the same time, supply voltage vcchv2 is decoupled from output voltage VccHV 241. This decoupling occurs when the transistors 220 and 235 are turned off. Driving a switch control signal at node 245 (to control transistor 220) to vcchv2, and another switch control signal at node 247 (to control transistor 235) to vcchv1 turns off transistor 220 and 235.

When the supply voltage vcchv1 is selected to be coupled with the output voltage VccHV 241, and node 247 is driven to vcchv1, the gate and the drain of transistor 235 have a similar potential. As a result, the transistor 235 is fully cut off. In contrast, in a conventional driver, node 247 driven may be driven to vcchv2. If vcchv2 were less than vcchv1, the gate and the drain of transistor 235 would have different potentials. Transistor 235 may not be fully cut off. Reverse current could flow in from the output. However, by driving node 247 to vcchv1 reverse current to flow back from output voltage VccHV 241 to the supply voltage vcchv2 may be prevented.

Similarly, supply voltage vcchv2 is coupled with output voltage VccHV 241 when the right-side transistors 220 and 235 are turned on. This occurs when node 245 is driven to vssh2 225 and node 247 is driven to vssh2. At the same time, supply voltage vcchv1 is decoupled from output voltage VccHV 241. This decoupling occurs when the transistors 219 and 234 are turned off. Driving node 244 to vcchv1, and node 246 to vcchv2, turns off transistors 219 and 234.

When supply voltage vcchv2 is selected to be coupled with output voltage VccHV 241, and the switch control signal at node 246 is driven to vcchv2, the gate and the drain of transistor 234 have a similar potential. As a result, transistor 234 is fully cut off. In contrast, in a conventional driver, the switch control signal at node 246 may be driven to vcchv1. If vcchv1 were less than vcchv2, the gate and the drain of transistor 234 would have different potentials. Transistor 234 may not be fully cut off. Reverse current could flow in from the output. However, by driving the switch control signal at node 246 to vcchv2 reverse current flow back from voltage VccHV 241 to the supply voltage vcchv1 may be prevented.

As described above, the gate and the drain of transistor 235 have a similar potential when the supply voltage vcchv1 is coupled with the output. Similarly, the gate and the drain of transistor 234 have a similar potential when the supply voltage is selected to be coupled with output. An advantage of embodiments described herein is that the similar potential at the gate and drain of transistors 235 and 234 is maintained even when the supply voltage vcchv1 or the supply voltage vcchv2 is ramping down. The respective voltages at nodes 246 and 247 track the voltage changes at the output voltage VccHV 241 in the event of a power supply failure. This is because the respective voltages at nodes 246 and 247 always come from the same power domain that is provided at output voltage VccHV 241 regardless of whether vcchv1 or vcchv2 is selected at the time. Advantageously, this feature prevents reverse in-rush current to a supply terminal in all cases, especially when either node 244 or node 245 is unreliable and has a lower potential.

An advantage of embodiments of described herein is that power multiplexing circuitry may be designed using thin gate devices for operation in a high voltage power domain. The cross-coupling technique and the dual-rail half-swing drivers make the voltage drop of the transistors very low for high current applications. This can prevent electrical overstress to transistors in the circuitry. For example, in a simulation using a 40 mA load under different process, voltage, and temperature assumptions, the voltage drop is about 0.005V or less for thin gate oxide devices. This compares with a voltage drop ranging between about 0.006V to as much as 0.0269V for thick gate oxide devices.

A further advantage is that the embodiments described herein do not require power isolation or a “power good” signal to guarantee reliability of a power supply during power up and power down transitions.

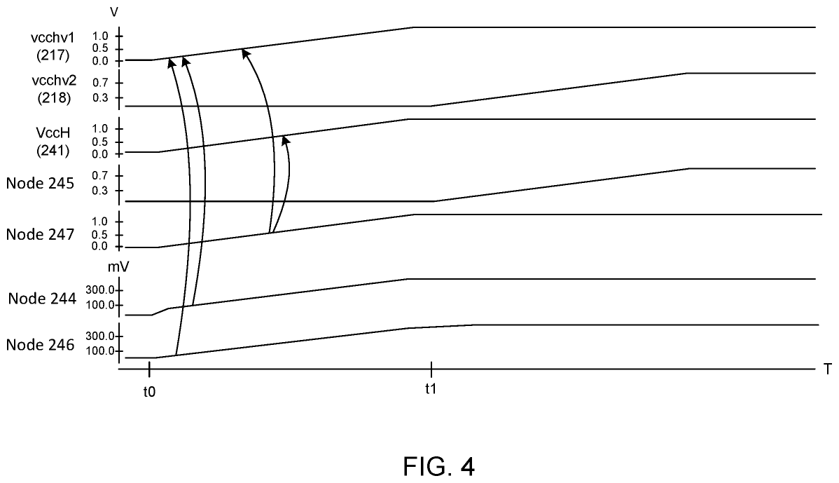

FIG. 4 shows a timing diagram illustrating a power supply ramp up operation according to an embodiment. The timing diagram is a simulation result showing the supply voltage vcchv1 starting to ramping up at time t0, and the supply voltage vcchv2 starting to ramping up at time t1. As vcchv1 ramps up, the voltages at node 244 and node 246 track vcchv1. (In this example, at t0, selvcchv1 can be 0, i.e. switches 220 and 235 can be selected.) It can be seen that when the supply voltage vcchv1 is greater than the supply voltage vcchv2, the voltage at node 247 tracks the output voltage VccHV 241 and the supply voltage vcchv1. The switch control signals at nodes 244, 245, 246, and 247, and the supply voltages vcchv1 and vcchv2 track one another during a power ramp up. This ensures that there is no reverse in-rush current or electrical overstress on the transistors.

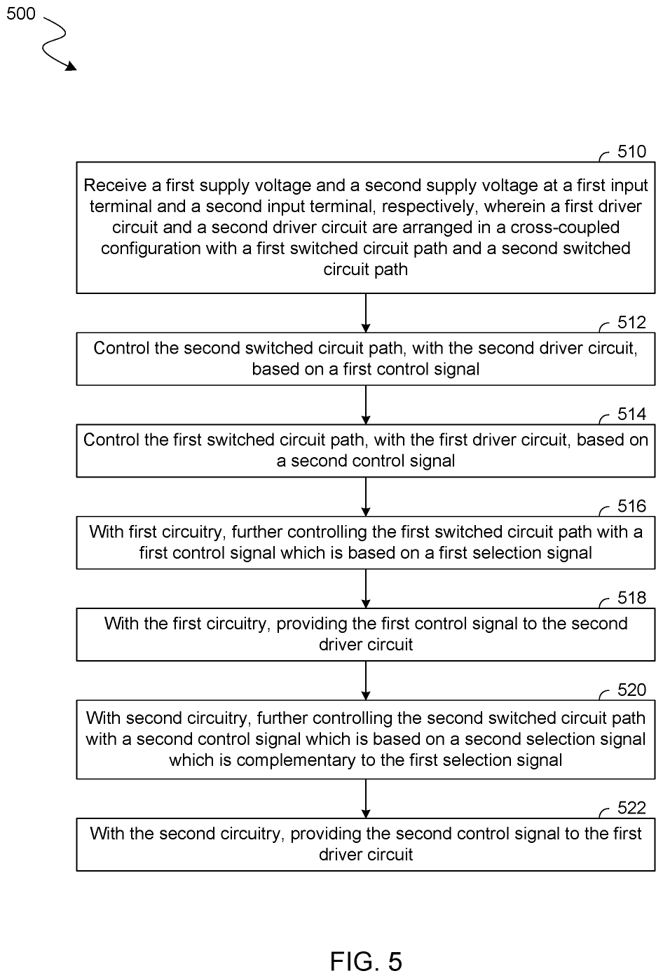

FIG. 5 shows features of a method 500 for operating power multiplexer circuitry according to one embodiment. Method 500 is one example of an embodiment wherein driver circuits, which are arranged in a cross-coupled configuration with each other, facilitate multiplexing functionality with which power is delivered based on a selected one of two supply voltages. In an embodiment, method 500 is performed with circuitry of one of devices 100, 200 (for example).

As shown in FIG. 5, method 500 comprises (at 510) receiving a first supply voltage and a second supply voltage at a first input terminal and a second input terminal, respectively, of a power multiplexer. The power multiplexer comprises a first switched circuit path, which is between the first input terminal and an output terminal, and a second switched circuit path which is between the second input terminal and the output terminal. A first driver circuit and a second driver circuit of the power multiplexer are arranged in a cross-coupled configuration with a first switched circuit path and a second switched circuit path. In the example embodiment of device 200, the first supply voltage and the second supply voltage are supply voltages vcchv1, vcchv2 (respectively)—e.g., wherein the first switched circuit path comprises transistors 219, 234, and wherein the second switched circuit path comprises transistors 220, 235. In one such embodiment, the first driver circuit is driver circuitry 203—e.g., wherein the second driver circuit is driver circuitry 204

Method 500 further comprises (at 512) controlling the second switched circuit path, with the second driver circuit, based on a first control signal (which, for example, is communicated on conductive line 228). Method 500 further comprises (at 514) controlling the first switched circuit path, with the first driver circuit, based on a second control signal (which, for example, is communicated on conductive line 227).

In an embodiment, method 500 further comprises (at 516) first circuitry of the power multiplexer further controlling the first switched circuit path with the first control signal—e.g., wherein the first circuitry comprises inverter 212 and buffer 215. In one such embodiment, the first control signal is generated based on a first selection signal (such as the signal selvcchv1_hv which is provided on conductive line 242). Method 500 further comprises (at 518) the first circuitry providing the first control signal to the second driver circuit—e.g., via conductive line 228.

Method 500 further comprises (at 520) second circuitry of the power multiplexer further controlling the second switched circuit path with a second control signal—e.g., wherein the second circuitry comprises buffer 222 and inverter 224. The second control signal is generated, for example, based on a second selection signal which is complementary to the first selection signal—e.g., wherein the second selection signal is the signal selvcchv2_hv 243. Method 500 further comprises (at 522) the second circuitry providing the second control signal to the first driver circuit—e.g., via conductive line 227.

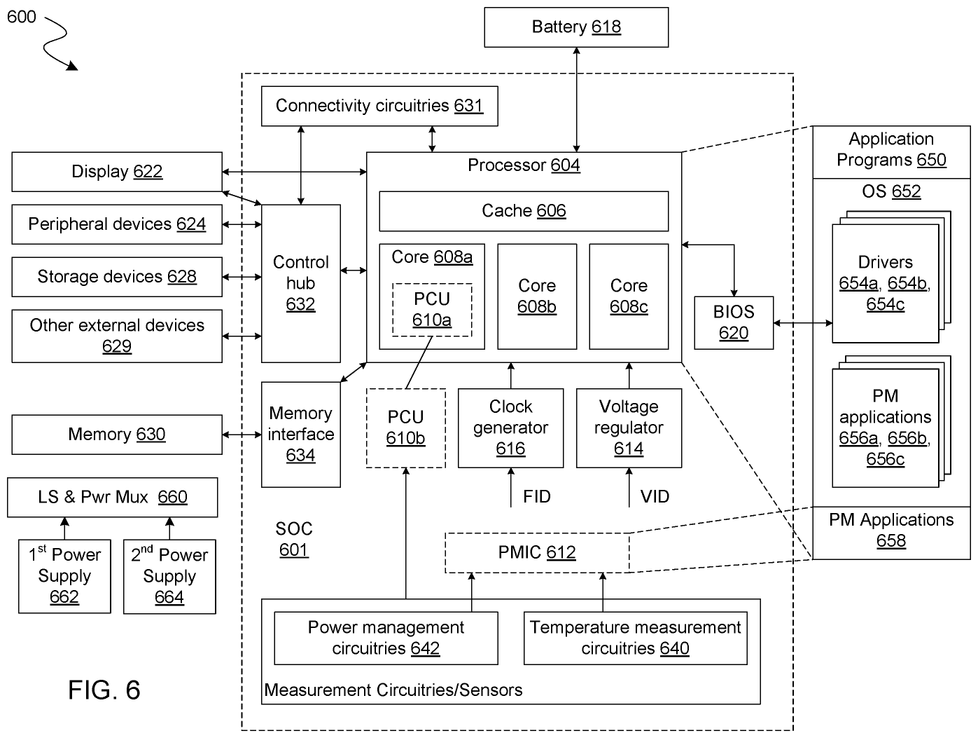

FIG. 6 illustrates a computer system or computing device 600 (also referred to as device 600), comprising voltage level shifting and power multiplexing circuitry for switching between two power sources, in accordance with some embodiments. It is pointed out that those elements of FIG. 6 having the same reference numbers (or names) as the elements of any other figure can operate or function in any manner similar to that described, but are not limited to such.

In some embodiments, device 600 represents an appropriate computing device, such as a computing tablet, a mobile phone or smart-phone, a laptop, a desktop, an Internet-of-Things (IoT) device, a server, a wearable device, a set-top box, a wireless-enabled e-reader, or the like. It will be understood that certain components are shown generally, and not all components of such a device are shown in device 600.

In an example, the device 600 comprises a SOC (System-on-Chip) 601. An example boundary of the SOC 601 is illustrated using dotted lines in FIG. 6, with some example components being illustrated to be included within SOC 601—however, SOC 601 may include any appropriate components of device 600.

In some embodiments, device 600 includes processor 604. Processor 604 can include one or more physical devices, such as microprocessors, application processors, microcontrollers, programmable logic devices, processing cores, or other processing means. The processing operations performed by processor 604 include the execution of an operating platform or operating system on which applications and/or device functions are executed. The processing operations include operations related to I/O (input/output) with a human user or with other devices, operations related to power management, operations related to connecting computing device 600 to another device, and/or the like. The processing operations may also include operations related to audio I/O and/or display I/O.

In some embodiments, processor 604 includes multiple processing cores (also referred to as cores) 608a, 608b, 608c. Although merely three cores 608a, 608b, 608c are illustrated in FIG. 6, the processor 604 may include any other appropriate number of processing cores, e.g., tens, or even hundreds of processing cores. Processor cores 608a, 608b, 608c may be implemented on a single integrated circuit (IC) chip. Moreover, the chip may include one or more shared and/or private caches, buses or interconnections, graphics and/or memory controllers, or other components.

In some embodiments, processor 604 includes cache 606. In an example, sections of cache 606 may be dedicated to individual cores 608 (e.g., a first section of cache 606 dedicated to core 608a, a second section of cache 606 dedicated to core 608b, and so on). In an example, one or more sections of cache 606 may be shared among two or more of cores 608. Cache 606 may be split in different levels, e.g., level 1 (L1) cache, level 2 (L2) cache, level 3 (L3) cache, etc.

In some embodiments, a given processor core (e.g., core 608a) may include a fetch unit to fetch instructions (including instructions with conditional branches) for execution by the core 608a. The instructions may be fetched from any storage devices such as the memory 630. Processor core 608a may also include a decode unit to decode the fetched instruction. For example, the decode unit may decode the fetched instruction into a plurality of micro-operations. Processor core 608a may include a schedule unit to perform various operations associated with storing decoded instructions. For example, the schedule unit may hold data from the decode unit until the instructions are ready for dispatch, e.g., until all source values of a decoded instruction become available. In one embodiment, the schedule unit may schedule and/or issue (or dispatch) decoded instructions to an execution unit for execution.

The execution unit may execute the dispatched instructions after they are decoded (e.g., by the decode unit) and dispatched (e.g., by the schedule unit). In an embodiment, the execution unit may include more than one execution unit (such as an imaging computational unit, a graphics computational unit, a general-purpose computational unit, etc.). The execution unit may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit.

Further, an execution unit may execute instructions out-of-order. Hence, processor core 608a (for example) may be an out-of-order processor core in one embodiment. Processor core 608a may also include a retirement unit. The retirement unit may retire executed instructions after they are committed. In an embodiment, retirement of the executed instructions may result in processor state being committed from the execution of the instructions, physical registers used by the instructions being de-allocated, etc. The processor core 608a may also include a bus unit to enable communication between components of the processor core 608a and other components via one or more buses. Processor core 608a may also include one or more registers to store data accessed by various components of the core 608a (such as values related to assigned app priorities and/or sub-system states (modes) association.

In some embodiments, device 600 comprises connectivity circuitries 631. For example, connectivity circuitries 631 includes hardware devices (e.g., wireless and/or wired connectors and communication hardware) and/or software components (e.g., drivers, protocol stacks), e.g., to enable device 600 to communicate with external devices. Device 600 may be separate from the external devices, such as other computing devices, wireless access points or base stations, etc.

In an example, connectivity circuitries 631 may include multiple different types of connectivity. To generalize, the connectivity circuitries 631 may include cellular connectivity circuitries, wireless connectivity circuitries, etc. Cellular connectivity circuitries of connectivity circuitries 631 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, 3rd Generation Partnership Project (3GPP) Universal Mobile Telecommunications Systems (UMTS) system or variations or derivatives, 3GPP Long-Term Evolution (LTE) system or variations or derivatives, 3GPP LTE-Advanced (LTE-A) system or variations or derivatives, Fifth Generation (5G) wireless system or variations or derivatives, 5G mobile networks system or variations or derivatives, 5G New Radio (NR) system or variations or derivatives, or other cellular service standards. Wireless connectivity circuitries (or wireless interface) of the connectivity circuitries 631 refers to wireless connectivity that is not cellular, and can include personal area networks (such as Bluetooth, Near Field, etc.), local area networks (such as Wi-Fi), and/or wide area networks (such as WiMax), and/or other wireless communication. In an example, connectivity circuitries 631 may include a network interface, such as a wired or wireless interface, e.g., so that a system embodiment may be incorporated into a wireless device, for example, cell phone or personal digital assistant.

In some embodiments, device 600 comprises control hub 632, which represents hardware devices and/or software components related to interaction with one or more I/O devices. For example, processor 604 may communicate with one or more of display 622, one or more peripheral devices 624, storage devices 628, one or more other external devices 629, etc., via control hub 632. Control hub 632 may be a chipset, a Platform Control Hub (PCH), and/or the like.

For example, control hub 632 illustrates one or more connection points for additional devices that connect to device 600, e.g., through which a user might interact with the system. For example, devices (e.g., devices 629) that can be attached to device 600 include microphone devices, speaker or stereo systems, audio devices, video systems or other display devices, keyboard or keypad devices, or other I/O devices for use with specific applications such as card readers or other devices.

As mentioned above, control hub 632 can interact with audio devices, display 622, etc. For example, input through a microphone or other audio device can provide input or commands for one or more applications or functions of device 600. Additionally, audio output can be provided instead of, or in addition to display output. In another example, if display 622 includes a touch screen, display 622 also acts as an input device, which can be at least partially managed by control hub 632. There can also be additional buttons or switches on computing device 600 to provide I/O functions managed by control hub 632. In one embodiment, control hub 632 manages devices such as accelerometers, cameras, light sensors or other environmental sensors, or other hardware that can be included in device 600. The input can be part of direct user interaction, as well as providing environmental input to the system to influence its operations (such as filtering for noise, adjusting displays for brightness detection, applying a flash for a camera, or other features).

In some embodiments, control hub 632 may couple to various devices using any appropriate communication protocol, e.g., PCIe (Peripheral Component Interconnect Express), USB (Universal Serial Bus), Thunderbolt, High Definition Multimedia Interface (HDMI), Firewire, etc.

In some embodiments, display 622 represents hardware (e.g., display devices) and software (e.g., drivers) components that provide a visual and/or tactile display for a user to interact with device 600. Display 622 may include a display interface, a display screen, and/or hardware device used to provide a display to a user. In some embodiments, display 622 includes a touch screen (or touch pad) device that provides both output and input to a user. In an example, display 622 may communicate directly with the processor 604. Display 622 can be one or more of an internal display device, as in a mobile electronic device or a laptop device or an external display device attached via a display interface (e.g., DisplayPort, etc.). In one embodiment display 622 can be a head mounted display (HMD) such as a stereoscopic display device for use in virtual reality (VR) applications or augmented reality (AR) applications.

In some embodiments and although not illustrated in the figure, in addition to (or instead of) processor 604, device 600 may include Graphics Processing Unit (GPU) comprising one or more graphics processing cores, which may control one or more aspects of displaying contents on display 622.

Control hub 632 (or platform controller hub) may include hardware interfaces and connectors, as well as software components (e.g., drivers, protocol stacks) to make peripheral connections, e.g., to peripheral devices 624.

It will be understood that device 600 could both be a peripheral device to other computing devices, as well as have peripheral devices connected to it. Device 600 may have a “docking” connector to connect to other computing devices for purposes such as managing (e.g., downloading and/or uploading, changing, synchronizing) content on device 600. Additionally, a docking connector can allow device 600 to connect to certain peripherals that allow computing device 600 to control content output, for example, to audiovisual or other systems.

In addition to a proprietary docking connector or other proprietary connection hardware, device 600 can make peripheral connections via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, connectivity circuitries 631 may be coupled to control hub 632, e.g., in addition to, or instead of, being coupled directly to the processor 604. In some embodiments, display 622 may be coupled to control hub 632, e.g., in addition to, or instead of, being coupled directly to processor 604.

In some embodiments, device 600 comprises memory 630 coupled to processor 604 via memory interface 634. Memory 630 includes memory devices for storing information in device 600. Memory can include nonvolatile (state does not change if power to the memory device is interrupted) and/or volatile (state is indeterminate if power to the memory device is interrupted) memory devices. Memory device 630 can be a dynamic random access memory (DRAM) device, a static random access memory (SRAM) device, flash memory device, phase-change memory device, or some other memory device having suitable performance to serve as process memory. In one embodiment, memory 630 can operate as system memory for device 600, to store data and instructions for use when the one or more processors 604 executes an application or process. Memory 630 can store application data, user data, music, photos, documents, or other data, as well as system data (whether long-term or temporary) related to the execution of the applications and functions of device 600.

Elements of various embodiments and examples are also provided as a machine-readable medium (e.g., memory 630) for storing the computer-executable instructions (e.g., instructions to implement any other processes discussed herein). The machine-readable medium (e.g., memory 630) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, device 600 comprises temperature measurement circuitries 640, e.g., for measuring temperature of various components of device 600. In an example, temperature measurement circuitries 640 may be embedded, or coupled or attached to various components, whose temperature are to be measured and monitored. For example, temperature measurement circuitries 640 may measure temperature of (or within) one or more of cores 608a, 608b, 608c, voltage regulator 614, memory 630, a mother-board of SOC 601, and/or any appropriate component of device 600.

In some embodiments, device 600 comprises power measurement circuitries 642, e.g., for measuring power consumed by one or more components of the device 600. In an example, in addition to, or instead of, measuring power, the power measurement circuitries 642 may measure voltage and/or current. In an example, the power measurement circuitries 642 may be embedded, or coupled or attached to various components, whose power, voltage, and/or current consumption are to be measured and monitored. For example, power measurement circuitries 642 may measure power, current and/or voltage supplied by one or more voltage regulators 614, power supplied to SOC 601, power supplied to device 600, power consumed by processor 604 (or any other component) of device 600, etc.

In some embodiments, device 600 comprises one or more voltage regulator circuitries, generally referred to as voltage regulator (VR) 614. VR 614 generates signals at appropriate voltage levels, which may be supplied to operate any appropriate components of the device 600. Merely as an example, VR 614 is illustrated to be supplying signals to processor 604 of device 600. In some embodiments, VR 614 receives one or more Voltage Identification (VID) signals, and generates the voltage signal at an appropriate level, based on the VID signals. Various type of VRs may be utilized for the VR 614. For example, VR 614 may include a “buck” VR, “boost” VR, a combination of buck and boost VRs, low dropout (LDO) regulators, switching DC-DC regulators, etc. Buck VR is generally used in power delivery applications in which an input voltage needs to be transformed to an output voltage in a ratio that is smaller than unity. Boost VR is generally used in power delivery applications in which an input voltage needs to be transformed to an output voltage in a ratio that is larger than unity. In some embodiments, each processor core has its own VR which is controlled by PCU 610a/b and/or PMIC 612. In some embodiments, each core has a network of distributed LDOs to provide efficient control for power management. The LDOs can be digital, analog, or a combination of digital or analog LDOs.

In some embodiments, device 600 comprises one or more clock generator circuitries, generally referred to as clock generator 616. Clock generator 616 generates clock signals at appropriate frequency levels, which may be supplied to any appropriate components of device 600. Merely as an example, clock generator 616 is illustrated to be supplying clock signals to processor 604 of device 600. In some embodiments, clock generator 616 receives one or more Frequency Identification (FID) signals, and generates the clock signals at an appropriate frequency, based on the FID signals.

In some embodiments, device 600 comprises battery 618 supplying power to various components of device 600. Merely as an example, battery 618 is illustrated to be supplying power to processor 604. Although not illustrated in the figures, device 600 may comprise a charging circuitry, e.g., to recharge the battery, based on Alternating Current (AC) power supply received from an AC adapter.

In some embodiments, device 600 comprises Power Control Unit (PCU) 610 (also referred to as Power Management Unit (PMU), Power Controller, etc.). In an example, some sections of PCU 610 may be implemented by one or more processing cores 608, and these sections of PCU 610 are symbolically illustrated using a dotted box and labelled PCU 610a. In an example, some other sections of PCU 610 may be implemented outside the processing cores 608, and these sections of PCU 610 are symbolically illustrated using a dotted box and labelled as PCU 610b. PCU 610 may implement various power management operations for device 600. PCU 610 may include hardware interfaces, hardware circuitries, connectors, registers, etc., as well as software components (e.g., drivers, protocol stacks), to implement various power management operations for device 600.

In some embodiments, device 600 comprises Power Management Integrated Circuit (PMIC) 612, e.g., to implement various power management operations for device 600. In some embodiments, PMIC 612 is a Reconfigurable Power Management ICs (RPMICs) and/or an IMVP (Intel® Mobile Voltage Positioning). In an example, the PMIC is within an IC chip separate from processor 604. The may implement various power management operations for device 600. PMIC 612 may include hardware interfaces, hardware circuitries, connectors, registers, etc., as well as software components (e.g., drivers, protocol stacks), to implement various power management operations for device 600.

In an example, device 600 comprises one or both PCU 610 or PMIC 612. In an example, any one of PCU 610 or PMIC 612 may be absent in device 600, and hence, these components are illustrated using dotted lines.

Various power management operations of device 600 may be performed by PCU 610, by PMIC 612, or by a combination of PCU 610 and PMIC 612. For example, PCU 610 and/or PMIC 612 may select a power state (e.g., P-state) for various components of device 600. For example, PCU 610 and/or PMIC 612 may select a power state (e.g., in accordance with the ACPI (Advanced Configuration and Power Interface) specification) for various components of device 600. Merely as an example, PCU 610 and/or PMIC 612 may cause various components of the device 600 to transition to a sleep state, to an active state, to an appropriate C state (e.g., CO state, or another appropriate C state, in accordance with the ACPI specification), etc. In an example, PCU 610 and/or PMIC 612 may control a voltage output by VR 614 and/or a frequency of a clock signal output by the clock generator, e.g., by outputting the VID signal and/or the FID signal, respectively. In an example, PCU 610 and/or PMIC 612 may control battery power usage, charging of battery 618, and features related to power saving operation.

The clock generator 616 can comprise a phase locked loop (PLL), frequency locked loop (FLL), or any suitable clock source. In some embodiments, each core of processor 604 has its own clock source. As such, each core can operate at a frequency independent of the frequency of operation of the other core. In some embodiments, PCU 610 and/or PMIC 612 performs adaptive or dynamic frequency scaling or adjustment. For example, clock frequency of a processor core can be increased if the core is not operating at its maximum power consumption threshold or limit. In some embodiments, PCU 610 and/or PMIC 612 determines the operating condition of each core of a processor, and opportunistically adjusts frequency and/or power supply voltage of that core without the core clocking source (e.g., PLL of that core) losing lock when the PCU 610 and/or PMIC 612 determines that the core is operating below a target performance level. For example, if a core is drawing current from a power supply rail less than a total current allocated for that core or processor 604, then PCU 610 and/or PMIC 612 can temporarily increase the power draw for that core or processor 604 (e.g., by increasing clock frequency and/or power supply voltage level) so that the core or processor 604 can perform at a higher performance level. As such, voltage and/or frequency can be increased temporality for processor 604 without violating product reliability.

In an example, PCU 610 and/or PMIC 612 may perform power management operations, e.g., based at least in part on receiving measurements from power measurement circuitries 642, temperature measurement circuitries 640, charge level of battery 618, and/or any other appropriate information that may be used for power management. To that end, PMIC 612 is communicatively coupled to one or more sensors to sense/detect various values/variations in one or more factors having an effect on power/thermal behavior of the system/platform. Examples of the one or more factors include electrical current, voltage droop, temperature, operating frequency, operating voltage, power consumption, inter-core communication activity, etc. One or more of these sensors may be provided in physical proximity (and/or thermal contact/coupling) with one or more components or logic/IP blocks of a computing system. Additionally, sensor(s) may be directly coupled to PCU 610 and/or PMIC 612 in at least one embodiment to allow PCU 610 and/or PMIC 612 to manage processor core energy at least in part based on value(s) detected by one or more of the sensors.

Also illustrated is an example software stack of device 600 (although not all elements of the software stack are illustrated). Merely as an example, processors 604 may execute application programs 650, Operating System 652, one or more Power Management (PM) specific application programs (e.g., generically referred to as PM applications 658), and/or the like. PM applications 658 may also be executed by the PCU 610 and/or PMIC 612. OS 652 may also include one or more PM applications 656a, 656b, 656c. The OS 652 may also include various drivers 654a, 654b, 654c, etc., some of which may be specific for power management purposes. In some embodiments, device 600 may further comprise a Basic Input/Output System (BIOS) 620. BIOS 620 may communicate with OS 652 (e.g., via one or more drivers 654), communicate with processors 604, etc.

For example, one or more of PM applications 658, 656, drivers 654, BIOS 620, etc. may be used to implement power management specific tasks, e.g., to control voltage and/or frequency of various components of device 600, to control wake-up state, sleep state, and/or any other appropriate power state of various components of device 600, control battery power usage, charging of the battery 618, features related to power saving operation, etc.

In various embodiments, device 600 comprises level shifting and power multiplexing circuitry 660 for switching between two power sources, a first power supply 662, and a second power supply 664. Level shifting and power multiplexing circuitry 660 may be configured to switch between the first and second power supplies 662 and 664, between battery 618 and another power supply, or between any suitable pair of power supplies or sources. Level shifting and power multiplexing circuitry 660 may provide power via an output coupled with a component within SOC 601, or coupled with a device or component external to SOC 610, such as display 622, peripheral devices 624, storage devices 628, other external devices 629, or memory 630. Level shifting and/or power multiplexing circuitry 660 may be located on board SOC 601 or on an IC separate from SOC 601. Similarly, first and/or second power supplies 662, 664 may be located on board SOC 601 or on an IC separate from SOC 601.

In the description herein, numerous details are discussed to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including circuitry to multiplex two voltage supplies.

Techniques and architectures for determining switching between two voltage supplies are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Following examples are provided to illustrate the various embodiments. These examples can depend from one another in any suitable manner.

In one or more first embodiments, a device comprises a first switched circuit path between a first input terminal and an output terminal, a second switched circuit path between a second input terminal and the output terminal, and a first driver circuit and a second driver circuit which are arranged in a cross-coupled configuration with the first switched circuit path and the second switched circuit path, wherein the second driver circuit is to control the second switched circuit path based on a first control signal, and wherein the first driver circuit is to control the first switched circuit path based on a second control signal.

In one or more second embodiments, further to the first embodiment, the device further comprises first circuitry which is coupled to receive a first selection signal, to further control the first switched circuit path with the first control signal, which is based on the first selection signal, and to provide the first control signal to the second driver circuit, and second circuitry which is coupled to receive a second selection signal which is complementary to the first selection signal, to further control the second switched circuit path with the second control signal, which is based on the second selection signal, and to provide the second control signal to the first driver circuit.

In one or more third embodiments, further to the second embodiment, the first switched circuit path comprises a first switch and a second switch coupled in series with each other between a first node and a second node, the first node to receive a first supply voltage, the second switched circuit path comprises a third switch and a fourth switch coupled in series with each other between a third node and the second node, the third node to receive a second supply voltage, the first circuitry is to control the first switch based on the first control signal, the second circuitry is to control the third switch based on the second control signal, the first driver circuit is to generate a third control signal, based on the second control signal, to control the second switch, and the second driver circuit is to generate a fourth control signal, based on the first control signal, to control the fourth switch.

In one or more fourth embodiments, further to the third embodiment, the device further comprises a processor and a memory coupled to receive power from the power multiplexer based on one of the first supply voltage or the second supply voltage.

In one or more fifth embodiments, further to the third embodiment or the fourth embodiment, the first driver circuit and the second driver circuit are further coupled to receive the first selection signal and the second selection signal, respectively, the first driver circuit is to generate the third control signal further based on the first selection signal, and the second driver circuit is to generate the fourth control signal further based on the second selection signal.

In one or more sixth embodiments, further to any of the third through fifth embodiments, the first driver circuit comprises a first transistor and a second transistor coupled in series with each other between the third node and a fourth node, wherein the first transistor and second transistor are of a first conductivity type, and the first driver circuit is to provide the third control signal at the fourth node, and a third transistor and a fourth transistor coupled in series with each other between the fourth node and a fifth node, wherein the third transistor and fourth transistor are of a second conductivity type, the fifth node is to receive a third supply voltage, wherein the third supply voltage is generated from the first supply voltage, and the first supply voltage and the second supply voltage are each greater than the third supply voltage.

In one or more seventh embodiments, further to the sixth embodiment, a gate of the second switch is coupled with the fourth node to receive the third control signal, and the third control signal comprises a voltage in a range from the second supply voltage to the third supply voltage.

In one or more eighth embodiments, further to any of the third through fifth embodiments, the device further comprises first level shifting circuitry to generate the first selection signal based on a first enable signal, wherein the first selection signal is to be in a first range from the first supply voltage to a third supply voltage, wherein the first supply voltage is to be greater than the third supply voltage, the first enable signal is to be in a second range from a fourth supply voltage to a fifth supply voltage, wherein the fourth supply voltage is to be greater than the fifth supply voltage, and the third supply voltage is to be greater than the fifth supply voltage.

In one or more ninth embodiments, further to the eighth embodiment, the second range of voltages is greater than the first range of voltages.

In one or more tenth embodiments, further to the eighth embodiment, the first range of voltages is less than 1.069 Volts, and greater than 0.7 Volts.

In one or more eleventh embodiments, further to any of the third through fifth embodiments, the device further comprises first level shifting circuitry to generate the first selection signal based on a first enable signal, second level shifting circuitry to generate the second selection signal based on a second enable signal, wherein the second enable signal is complementary to the first enable signal, and an inverter to generate the second enable signal from the first enable signal.

In one or more twelfth embodiments, further to any of the third through fifth embodiments, the first circuitry comprises first inverter circuitry to receive the first selection signal and to generate the first control signal, first buffer circuitry to receive the first control signal and to provide the first control signal to the first switch, and wherein the second node is to provide an output supply voltage.

In one or more thirteenth embodiments, a power multiplexer comprises a first switched circuit path which extends to each of a first input terminal of the power multiplexer and an output terminal of the power multiplexer, a second switched circuit path which extends to each of a second input terminal of the power multiplexer and the output terminal, a first driver circuit and a second driver circuit, first circuitry to generate a first control signal based on a first selection signal, wherein the first circuitry is coupled to control the first switched circuit path based on the first control signal, and further to provide the first control signal to the second driver circuit, and second circuitry to generate a second control signal based on a second selection signal, wherein the second circuitry is coupled to control the second switched circuit path based on the second control signal, and further to provide the second control signal to the first driver circuit, wherein the first driver circuit is coupled to further control the first switched circuit path based on the second control signal, and wherein the second driver circuit is coupled to further control the second switched circuit path based on the first control signal.

In one or more fourteenth embodiments, further to the thirteenth embodiment, the first switched circuit path comprises a first switch and a second switch coupled in series with each other between a first node and a second node, the first node to receive a first supply voltage, the second switched circuit path comprises a third switch and a fourth switch coupled in series with each other between a third node and the second node, the third node to receive a second supply voltage, the first circuitry is to control the first switch based on the first control signal, the second circuitry is to control the third switch based on the second control signal, the first driver circuit is to generate a third control signal, based on the second control signal, to control the second switch, and the second driver circuit is to generate a fourth control signal, based on the first control signal, to control the fourth switch.

In one or more fifteenth embodiments, further to the fourteenth embodiment, the first driver circuit and the second driver circuit are further coupled to receive the first selection signal and the second selection signal, respectively, the first driver circuit is to generate the third control signal further based on the first selection signal, and the second driver circuit is to generate the fourth control signal further based on the second selection signal.

In one or more sixteenth embodiments, further to the fourteenth embodiment or the fifteenth embodiment, the first driver circuit comprises a first transistor and a second transistor coupled in series with each other between the third node and a fourth node, wherein the first transistor and second transistor are of a first conductivity type, and the first driver circuit is to provide the third control signal at the fourth node, and a third transistor and a fourth transistor coupled in series with each other between the fourth node and a fifth node, wherein the third transistor and fourth transistor are of a second conductivity type, the fifth node is to receive a third supply voltage, wherein the third supply voltage is generated from the first supply voltage, and the first supply voltage and the second supply voltage are each greater than the third supply voltage.

In one or more seventeenth embodiments, further to the sixteenth embodiment, a gate of the second switch is coupled with the fourth node to receive the third control signal, and the third control signal comprises a voltage in a range from the second supply voltage to the third supply voltage.

In one or more eighteenth embodiments, further to any of the fourteenth through sixteenth embodiments, the first circuitry comprises first inverter circuitry to receive the first selection signal and to generate the first control signal, first buffer circuitry to receive the first control signal and to provide the first control signal to the first switch, and wherein the second node is to provide an output supply voltage.

In one or more nineteenth embodiments, a method at a power multiplexer comprises receiving a first supply voltage and a second supply voltage at a first input terminal and a second input terminal, respectively, wherein a first switched circuit path is between the first input terminal and an output terminal, wherein a second switched circuit path between the second input terminal and the output terminal, and wherein a first driver circuit and a second driver circuit are arranged in a cross-coupled configuration with the first switched circuit path and the second switched circuit path, with the second driver circuit, controlling the second switched circuit path based on a first control signal, and with the first driver circuit, controlling the first switched circuit path based on a second control signal.

In one or more twentieth embodiments, further to the nineteenth embodiment, the method further comprises with first circuitry further controlling the first switched circuit path with the first control signal, which is based on a first selection signal, and providing the first control signal to the second driver circuit, and with second circuitry further controlling the second switched circuit path with the second control signal, which is based on a second selection signal which is complementary to the first selection signal, and providing the second control signal to the first driver circuit.

In one or more twenty-first embodiments, further to the twentieth embodiment, the first switched circuit path comprises a first switch and a second switch coupled in series with each other between a first node and a second node, the second switched circuit path comprises a third switch and a fourth switch coupled in series with each other between a third node and the second node, the first circuitry controls the first switch based on the first control signal, the second circuitry controls the third switch based on the second control signal, the first driver circuit generates a third control signal, based on the second control signal, to control the second switch, and the second driver circuit generates a fourth control signal, based on the first control signal, to control the fourth switch.

In one or more twenty-second embodiments, further to the twenty-first embodiment, the first driver circuit and the second driver circuit receive the first selection signal and the second selection signal, respectively, the first driver circuit generates the third control signal further based on the first selection signal, and the second driver circuit generates the fourth control signal further based on the second selection signal.

In one or more twenty-third embodiments, further to the twenty-first embodiment or the twenty-second embodiment, the first driver circuit comprises a first transistor and a second transistor coupled in series with each other between the third node and a fourth node, wherein the first transistor and second transistor are of a first conductivity type, and the first driver circuit provides the third control signal at the fourth node, a third transistor and a fourth transistor coupled in series with each other between the fourth node and a fifth node, wherein the third transistor and fourth transistor are of a second conductivity type, the fifth node receives a third supply voltage, wherein the third supply voltage is generated from the first supply voltage, and the first supply voltage and the second supply voltage are each greater than the third supply voltage.

In one or more twenty-fourth embodiments, further to the twenty-third embodiment, a gate of the second switch receives the third control signal via the fourth node, and the third control signal comprises a voltage in a range from the second supply voltage to the third supply voltage.

In one or more twenty-fifth embodiments, further to any of the twenty-first through twenty-third embodiments, the method further comprises, with first level shifting circuitry, generating the first selection signal based on a first enable signal, wherein the first selection signal is in a first range from the first supply voltage to a third supply voltage, wherein the first supply voltage is greater than the third supply voltage, the first enable signal is in a second range from a fourth supply voltage to a fifth supply voltage, wherein the fourth supply voltage is greater than the fifth supply voltage, and the third supply voltage is greater than the fifth supply voltage.

In one or more twenty-sixth embodiments, further to the twenty-fifth embodiment, the second range of voltages is greater than the first range of voltages.

In one or more twenty-seventh embodiments, further to the twenty-fifth embodiment, the first range of voltages is less than 1.069 Volts, and greater than 0.7 Volts.

In one or more twenty-eighth embodiments, further to any of the twenty-first through twenty-third embodiments, the method further comprises with first level shifting circuitry, generating the first selection signal based on a first enable signal, with second level shifting circuitry, generating the second selection signal based on a second enable signal, wherein the second enable signal is complementary to the first enable signal, and with an inverter circuit, generating the second enable signal from the first enable signal.

In one or more twenty-ninth embodiments, further to any of the twenty-first through twenty-third embodiments, the first circuitry comprises first inverter circuitry which receives the first selection signal and generates the first control signal, and first buffer circuitry which receives the first control signal and provides the first control signal to the first switch, wherein the second node provides an output supply voltage.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A device comprising:
a first switched circuit path between a first input terminal and an output terminal;
a second switched circuit path between a second input terminal and the output terminal; and
a first driver circuit and a second driver circuit which are arranged in a cross-coupled configuration with the first switched circuit path and the second switched circuit path, wherein the second driver circuit is to control the second switched circuit path based on a first control signal, and wherein the first driver circuit is to control the first switched circuit path based on a second control signal.

2. The device of claim 1, further comprising:
first circuitry which is coupled to receive a first selection signal, to further control the first switched circuit path with the first control signal, which is based on the first selection signal, and to provide the first control signal to the second driver circuit; and
second circuitry which is coupled to receive a second selection signal which is complementary to the first selection signal, to further control the second switched circuit path with the second control signal, which is based on the second selection signal, and to provide the second control signal to the first driver circuit.

3. The device of claim 2, wherein:
the first switched circuit path comprises a first switch and a second switch coupled in series with each other between a first node and a second node, the first node to receive a first supply voltage;
the second switched circuit path comprises a third switch and a fourth switch coupled in series with each other between a third node and the second node, the third node to receive a second supply voltage;
the first circuitry is to control the first switch based on the first control signal;
the second circuitry is to control the third switch based on the second control signal;
the first driver circuit is to generate a third control signal, based on the second control signal, to control the second switch; and
the second driver circuit is to generate a fourth control signal, based on the first control signal, to control the fourth switch.

4. The device of claim 3, further comprising a processor and a memory coupled to receive power from the power multiplexer based on one of the first supply voltage or the second supply voltage.

5. The device of claim 3, wherein:
the first driver circuit and the second driver circuit are further coupled to receive the first selection signal and the second selection signal, respectively;
the first driver circuit is to generate the third control signal further based on the first selection signal; and
the second driver circuit is to generate the fourth control signal further based on the second selection signal.

6. The device of claim 3, wherein the first driver circuit comprises:
a first transistor and a second transistor coupled in series with each other between the third node and a fourth node, wherein the first transistor and second transistor are of a first conductivity type, and the first driver circuit is to provide the third control signal at the fourth node; and
a third transistor and a fourth transistor coupled in series with each other between the fourth node and a fifth node, wherein the third transistor and fourth transistor are of a second conductivity type, the fifth node is to receive a third supply voltage, wherein the third supply voltage is generated from the first supply voltage, and the first supply voltage and the second supply voltage are each greater than the third supply voltage.

7. The device of claim 6, wherein a gate of the second switch is coupled with the fourth node to receive the third control signal, and the third control signal comprises a voltage in a range from the second supply voltage to the third supply voltage.

8. The device of claim 3, further comprising first level shifting circuitry to generate the first selection signal based on a first enable signal, wherein:
the first selection signal is to be in a first range from the first supply voltage to a third supply voltage, wherein the first supply voltage is to be greater than the third supply voltage;
the first enable signal is to be in a second range from a fourth supply voltage to a fifth supply voltage, wherein the fourth supply voltage is to be greater than the fifth supply voltage; and
the third supply voltage is to be greater than the fifth supply voltage.

9. The device of claim 8, wherein the second range of voltages is greater than the first range of voltages.

10. The device of claim 3, further comprising:
first level shifting circuitry to generate the first selection signal based on a first enable signal;
second level shifting circuitry to generate the second selection signal based on a second enable signal, wherein the second enable signal is complementary to the first enable signal; and
an inverter to generate the second enable signal from the first enable signal.

11. The device of claim 3, wherein the first circuitry comprises:
first inverter circuitry to receive the first selection signal and to generate the first control signal;
first buffer circuitry to receive the first control signal and to provide the first control signal to the first switch; and
wherein the second node is to provide an output supply voltage.

12. A power multiplexer comprising:
a first switched circuit path which extends to each of a first input terminal of the power multiplexer and an output terminal of the power multiplexer;
a second switched circuit path which extends to each of a second input terminal of the power multiplexer and the output terminal;
a first driver circuit and a second driver circuit;
first circuitry to generate a first control signal based on a first selection signal, wherein the first circuitry is coupled to control the first switched circuit path based on the first control signal, and further to provide the first control signal to the second driver circuit; and
second circuitry to generate a second control signal based on a second selection signal, wherein the second circuitry is coupled to control the second switched circuit path based on the second control signal, and further to provide the second control signal to the first driver circuit;
wherein the first driver circuit is coupled to further control the first switched circuit path based on the second control signal, and wherein the second driver circuit is coupled to further control the second switched circuit path based on the first control signal.

13. The power multiplexer of claim 12, wherein:
the first switched circuit path comprises a first switch and a second switch coupled in series with each other between a first node and a second node, the first node to receive a first supply voltage;
the second switched circuit path comprises a third switch and a fourth switch coupled in series with each other between a third node and the second node, the third node to receive a second supply voltage;
the first circuitry is to control the first switch based on the first control signal;
the second circuitry is to control the third switch based on the second control signal;
the first driver circuit is to generate a third control signal, based on the second control signal, to control the second switch; and
the second driver circuit is to generate a fourth control signal, based on the first control signal, to control the fourth switch.

14. The power multiplexer of claim 13, wherein:
the first driver circuit and the second driver circuit are further coupled to receive the first selection signal and the second selection signal, respectively;
the first driver circuit is to generate the third control signal further based on the first selection signal; and
the second driver circuit is to generate the fourth control signal further based on the second selection signal.

15. The power multiplexer of claim 13, wherein the first driver circuit comprises:
a first transistor and a second transistor coupled in series with each other between the third node and a fourth node, wherein the first transistor and second transistor are of a first conductivity type, and the first driver circuit is to provide the third control signal at the fourth node; and
a third transistor and a fourth transistor coupled in series with each other between the fourth node and a fifth node, wherein the third transistor and fourth transistor are of a second conductivity type, the fifth node is to receive a third supply voltage, wherein the third supply voltage is generated from the first supply voltage, and the first supply voltage and the second supply voltage are each greater than the third supply voltage.

16. The power multiplexer of claim 13, wherein the first circuitry comprises:
first inverter circuitry to receive the first selection signal and to generate the first control signal;
first buffer circuitry to receive the first control signal and to provide the first control signal to the first switch; and
wherein the second node is to provide an output supply voltage.

17. A method at a power multiplexer, the method comprising:
receiving a first supply voltage and a second supply voltage at a first input terminal and a second input terminal, respectively, wherein a first switched circuit path is between the first input terminal and an output terminal, wherein a second switched circuit path between the second input terminal and the output terminal, and wherein a first driver circuit and a second driver circuit are arranged in a cross-coupled configuration with the first switched circuit path and the second switched circuit path;
with the second driver circuit, controlling the second switched circuit path based on a first control signal; and
with the first driver circuit, controlling the first switched circuit path based on a second control signal.

18. The method of claim 17, further comprising:
with first circuitry:
further controlling the first switched circuit path with the first control signal, which is based on a first selection signal; and
providing the first control signal to the second driver circuit; and with second circuitry:
further controlling the second switched circuit path with the second control signal, which is based on a second selection signal which is complementary to the first selection signal; and
providing the second control signal to the first driver circuit.

19. The method of claim 18, wherein:
the first switched circuit path comprises a first switch and a second switch coupled in series with each other between a first node and a second node;
the second switched circuit path comprises a third switch and a fourth switch coupled in series with each other between a third node and the second node;
the first circuitry controls the first switch based on the first control signal;
the second circuitry controls the third switch based on the second control signal;
the first driver circuit generates a third control signal, based on the second control signal, to control the second switch; and
the second driver circuit generates a fourth control signal, based on the first control signal, to control the fourth switch.

20. The method of claim 19, wherein:
the first driver circuit and the second driver circuit receive the first selection signal and the second selection signal, respectively;
the first driver circuit generates the third control signal further based on the first selection signal; and
the second driver circuit generates the fourth control signal further based on the second selection signal.
